(19) United States
(12) Patent Application Publication
(10) Pub. No.: US 2019/0358768 A1
(43) Pub. Date: Nov. 28, 2019

(54) CARRIER HEAD FOR CHEMICAL MECHANICAL POLISHING DEVICE, INCLUDING CONTACT FLAP

(71) Applicant: Joon Mo KANG, Seongnam (KR)

(72) Inventor: Joon Mo KANG, Seongnam (KR)

(21) Appl. No.: 16/477,522

(22) PCT Filed: Sep. 4, 2017
(86) PCT No.: PCT/KR2017/009627

§ 371 Date: Jul. 11, 2019

(30) Foreign Application Priority Data
Feb. 1, 2017 (KR) 10-2017-0014667

(51) Int. Cl. B24B 37/32

(52) U.S. Cl. CPC B24B 37/32; H01L 21/30625

(57) ABSTRACT

A carrier head for a chemical mechanical polishing apparatus is provided. The carrier head includes a base and a substrate receiving member connected to a lower part of the base. Inside of the substrate receiving member, at least one contact flap is connected to the lower part of the base. The at least one contact flap includes a connecting portion, a side portion extended downwardly from the connecting portion and a contact portion extended sidewardly from a bottom end of the side portion. Adjacent to the at least one contact flap, at least one wall structure is connected to the lower part of the base to limit an expansion of the at least one contact flap for a firm contact of the contact portion with an inner surface of the substrate receiving member by means of fluid pressure.

### TECHNICAL FIELD

The present invention relates to a chemical mechanical polishing apparatus, and more particularly, to a carrier head comprising contact flap for applying polishing pressure to a substrate during a polishing process.

### BACKGROUND ART

When manufacturing semiconductor or glass substrates, and fabricating integrated circuits, a need to polish or planarize the surface of a substrate at particular steps has been increased. As a technology to satisfy the need, a chemical mechanical polishing (CMP) has been widely used.

In general, the CMP of a substrate is performed by attaching a polishing pad on a platen, mounting the substrate to a substrate receiving unit called a carrier head, and then, while applying slurry to the polishing pad, rotating the platen and carrier head simultaneously to generate friction between the polishing pad and the substrate.

Basically, the carrier head comprises a base receiving motive power from a drive shaft and providing space in which carrier parts are capable of being fixed, a substrate receiving member connected to a lower part of the base to receive and rotate the substrate, and a retaining ring supporting a side surface of the substrate during the polishing process to prevent the substrate from slipping out from the beneath of the carrier head. During polishing, the substrate is applied with polishing pressure through the substrate receiving member formed of a flexible membrane. Even though a uniform polishing pressure is applied to the entire substrate, there is a case that a particular area (for example a center area or an edge area of the substrate) shows a different removal rate according to the nature of polished film, polishing pad or slurry. In this case, to maintain a good polishing uniformity, it is necessary to control a polishing pressure separately in predetermined areas of a substrate.

FIG. 1 is a schematic cross-sectional view showing a conventional carrier head (KR Publication No. 10-2006-0044770). The carrier head comprises a base 104, a membrane 108 for receiving and applying pressure to a substrate 10, and a retaining ring 110. The membrane 108 comprises a perimeter portion 124 and annular inner flaps 128a, 128b extended upwardly from a plate which receives a substrate. The inner flaps 128a, 128b partition the membrane 108 by concentric circles, and thereby an inner chamber 106a, a middle chamber 106b and an outer chamber 106c are formed through the connection of the perimeter portion 124 and inner flaps 128a, 128b to a lower part of the base 104. By applying pressure independently to the pressurizing chambers 106a, 106b, 106c through passages 112a, 112b, 112c the pressure applied to each area of the substrate 10 can be varied. However, in this conventional carrier head, manufacturing the membrane becomes difficult as the number of inner flaps increases. There have been also drawbacks of bad polishing uniformity induced by a pressure difference between chambers at zones where inner flaps are branched.

### DISCLOSURE

### Technical Problem

The present invention has been made in view of the above-mentioned problems occurring in the prior art, and it is an object of the present invention to provide a carrier head comprising contact flap for a chemical mechanical polishing apparatus that is capable of independently applying polishing pressure to each predetermined area of a substrate during a chemical mechanical polishing.

### Technical Solution

In one aspect, the invention to achieve above-mentioned object is directed to a carrier head for a chemical mechanical polishing apparatus comprising contact flap. The carrier head comprises: a base; a substrate receiving member connected to a lower part of the base, having an outer surface for receiving a substrate and an inner surface at the opposite side of the outer surface; at least one contact flap positioned inside of the substrate receiving member comprising a connecting portion connected to the lower part of the base, a side portion extended downwardly from the connecting portion, a contact portion extended sidewardly from a bottom end of the side portion; at least one wall structure connected to the lower part of the base, the at least one wall structure being positioned adjacent to the at least one contact flap; wherein the at least one wall structure is configured to limit an expansion of the at least one contact flap for a firm contact of the contact portion with the inner surface by means of fluid pressure.

In another aspect of the present invention directed to a contact flap of a carrier head for a chemical mechanical polishing apparatus, the contact flap comprises: an annular contact portion having a bottom surface to provide a contact surface to a substrate receiving member and a top surface at the opposite side of the bottom surface; a side portion extended upwardly from the top surface; a connecting portion extended in a side direction from a top end of the side portion; wherein a protruding structure is formed on at least one corner where the top surface and the side portion meet each other.

In yet another aspect of the present invention directed to a contact flap of a carrier head for a chemical mechanical polishing apparatus, the contact flap comprises: an annular contact portion having a bottom surface to provide a contact surface to a substrate receiving member and a top surface at the opposite side of the bottom surface; a side portion extended upwardly from either an inner or outer edge of the top surface; a connecting portion extended in a side direction from a top end of the side portion, the side direction being opposite to an extended direction of the contact flap.

In still yet another aspect of the present invention directed to a contact flap of a carrier head for a chemical mechanical polishing apparatus, the contact flap comprises: an annular contact portion having a bottom surface to provide a contact surface to a substrate receiving member and a top surface at the opposite side of the bottom surface; a side portion extended upwardly from a surface between an inner and outer edge of the top surface; a connecting portion extended in a side direction from a top end of the side portion, the side direction being either inward or outward with respect to the side portion.

### Advantageous Effects

According to the present invention, a carrier head for a chemical mechanical polishing apparatus is capable of applying pressure independently to predetermined areas without the partitioning of a substrate receiving member, and thereby a sudden change of polishing uniformity can be suppressed at a transition zone of the areas.

### DESCRIPTION OF DRAWINGS

FIG. 1 is a schematic cross-sectional view showing a conventional carrier head.

FIG. 2 is a cross-sectional view of a carrier head for a chemical mechanical polishing apparatus according to an embodiment of the present invention.

FIG. 3 is a perspective sectional view of a contact flap.

FIG. 4 is a partial cross-sectional view of a contact flap.

FIG. 5 is a partial cross-sectional view showing behavior of a contact flap.

FIG. 6 is a partial cross-sectional view showing another example of a contact flap.

FIG. 7 is a partial cross-sectional view showing yet another example of a contact flap.

FIG. 8 is a partial cross-sectional view showing still yet another example of a contact flap.

FIG. 9 is a partial cross-sectional view showing still yet another example of a contact flap.

FIG. 10 is a cross-sectional view of a carrier head according to another embodiment of the present invention.

FIG. 11 is a cross-sectional view of a carrier head according to yet another embodiment of the present invention.

FIG. 12 is a cross-sectional view of a carrier head according to still yet another embodiment of the present invention.

FIGS. 13 and 14 are cross-sectional views showing still yet another example of a contact flap and a carrier head using this contact flap, respectively.

FIGS. 15 and 16 are cross-sectional views showing still yet another example of a contact flap and a carrier head using this contact flap, respectively.

FIG. 17 is a cross-sectional view showing still yet another example of a contact flap.

FIG. 18 is a partial cross-sectional view of a carrier head, and graphs of pressure variation according to the position of plate portion for explaining pressure dispersion by protruding structures.

FIG. 19 is a cross-sectional view of a contact flap showing another example of a protruding structure.

FIG. 20 is a cross-sectional view of a carrier head according to still yet another embodiment of the present invention.

FIG. 21 is a cross-sectional view of a carrier head according to still yet another embodiment of the present invention.

### BEST MODE FOR INVENTION

Hereinafter, preferred embodiments of the present invention will be explained with reference to the attached drawings. However, the invention is not limited to the disclosed embodiments hereinafter, but will be embodied in various forms. Rather, these embodiments of the present invention are provided in order to fully explain the present invention to those skilled in the art. Therefore, in the drawings, the sizes of components may be exaggerated for the clarity and convenience of the description.

In the description, when it is said that one member is connected “to a lower part” of another member, it means that one member may be connected to another member by contacting “lower part” as well as other members may exist between the two members and one member may be connected to yet another member. On the contrary, when it is said that one member is connected “directly to a lower part”, it means that another member may not exist between the two members. In the description, it should be noted that a same reference numeral in the drawings means a same component. Also, relative terms such as ‘on’ or ‘up’ and ‘beneath’ or ‘down’, as used herein are defined to describe the relationship of some components with other components as shown in the drawings. It should be understood that the relative terms include other directions of components inclusive of the directions as shown in the drawings. For example, if all components in the drawing are turned over, a component which located on another component becomes located beneath another component. Accordingly, for example, the term ‘on’ may include both of ‘on’ and ‘beneath’ depending on a specific direction of the drawings.

FIG. 2 is a cross-sectional view of a carrier head 900 for a chemical mechanical polishing apparatus comprising a contact flap 700 according to a preferred embodiment of the present invention. The carrier head 900 is built on a basis of a base 100 receiving motive power from a drive shaft 110. A retaining ring 120 is mounted to a lower part of the base 100 and serves to prevent a substrate (not shown) from slipping out during a polishing process. Inside of the retaining ring 120, a substrate receiving member 600 is connected to the lower part of the base 100.

The substrate receiving member 600 comprises a plate portion 610, a perimeter portion 620 and a securing portion 650. The plate portion 610 provides two surfaces defined as an outer surface 612 and an inner surface 614. The size and shape of the plate portion 610 conforms generally to the size and shape of a substrate (not shown) to be polished. The outer surface 612 is a substrate receiving surface against which a substrate is mounted and transferred. The inner surface 614, which is at the back of the outer surface 612, is a surface to which fluid pressure is applied. The perimeter portion 620 is a portion extended upwardly from an edge of the plate portion 610. Although the perimeter portion 620 is shown as perpendicular to the plate portion 610 in FIG. 2, the perimeter portion 620 is not necessarily to be perpendicular to the plate portion 610. It is sufficient for the perimeter portion 610 to be extended having a vertical component necessary for providing space for the connection thereof to the base 100. The securing portion 650 is extended from the perimeter portion and connected to the lower part of the base 100, and desirably has a shape of a flap. The securing portion 650 can have an O-ring structure 652 at the end to provide a secure sealing.

Inside of the substrate receiving member 600, a connecting portion 730 of a contact flap 700 is connected to the lower part of the base 100. A side portion 720 is extended downwardly from the connecting portion and a contact portion 710 is extended to an inward direction from a bottom end of the side portion 720. Here, the inward direction is defined as the direction heading to the center of the substrate receiving member 600 and the outward direction is defined as the direction moving away from the center. The contact flap 700 can be connected to the lower part of the base 100 by fastening a clamp 570 formed of metal or plastic with bolts (not shown).

A wall structure 530, connected to the lower part of the base 100, being positioned adjacently to and outside of the contact flap 700, then the wall structure 530 has a form of surrounding the contact flap 700. The position of the wall structure 530 is decided according to the extending direction of the contact portion 710. As shown in FIG. 2 if the contact portion 710 is extended to the inward direction, then the wall structure 530 is positioned in the outside which is opposite with respect to the side portion 720. The wall structure 530 is preferably made of substantially rigid material like metal or plastic. The wall structure 530 can be connected to the lower part of the base 100 also by using bolts (not shown).

When the wall structure 530 limits an expansion of the contact flap 700 by fluid pressure P2 applied through a fluid passage 310, the contact portion 710 comes to contact firmly the inner surface 614 of the substrate receiving member. If a firm contact is made with the inner surface 614, a pressurizing center chamber 300 is formed by taking the contact flap 700 as a chamber wall, say a boundary of the chamber. At the outside of the center chamber 300, an outer chamber 200 is formed by a pressure P1 applied through a fluid passage 210.

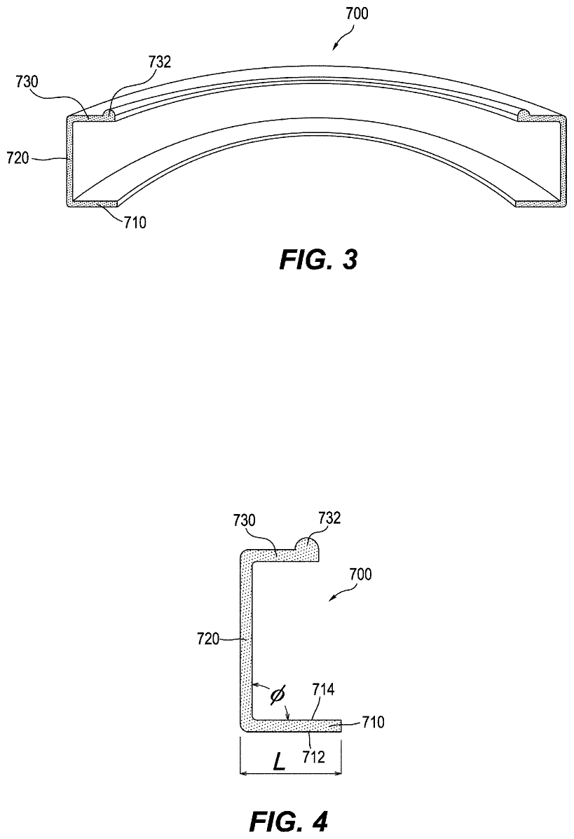

FIG. 3 is a perspective sectional view of a contact flap 700. The contact flap 700 comprises a contact portion 710, a side portion 720 and a connecting portion 730. On the whole the contact flap 700 has a ring-shape, and if only one side is cut, a cross section can have an image similar to “[”. The contact flap 700 has an open structure, so that it cannot form alone any chamber for keeping fluid therein even if the connecting portion 730 is connected to the lower part of the base 100. The contact flap 700 can form a pressurizing chamber when it is coupled to the substrate receiving member 600.

FIG. 4 is a partial cross-sectional view of the contact flap 700. The contact portion 710 has a bottom surface 712 providing a contact surface to the substrate receiving member and a top surface 714 at the opposite side of the bottom surface. An extended length L of the contact portion 710 is preferably longer than 3 mm. The side portion 720 is extended upwardly from the top surface 714 of the contact portion so that it provides space for the connection to the base 100. The side portion 720 is not necessarily to be perpendicular to the contact portion 710. It is preferred that the angle Θ in FIG. 4 is in a range of 90° to 120°. The connecting portion 730 can be extended in a side direction from a top end of the side portion 720 and is to be connected to the base 100. An O-ring structure 732 can be formed at the end of the connecting portion 730 for a secure sealing. The contact flap 700 is preferably formed of a flexible material, and rubbers such as silicone rubber, chloroprene rubber or ethylene propylene diene monomer (EPDM) rubber can be used as a flexible material. The thickness of the contact flap 700 except the O-ring structure can be from 0.3 mm to 6 mm for the contact portion 710 and from 0.3 mm to 3 mm for the side portion 720 and connecting portion 730.

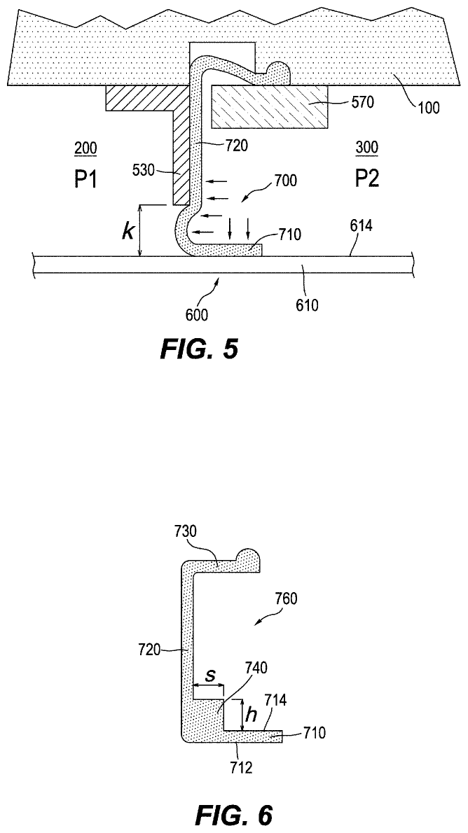

FIG. 5 is a partial cross-sectional view showing behavior of the contact flap 700. When the fluid pressure P2 in the center chamber 300 is higher than the pressure P1 in the outer chamber 200, fluid in the center chamber 300 moves the side portion 720 outwardly and the contact portion 710 downwardly as depicted by the straight arrows. At this time, the wall structure 530 contacts the side portion 720 and the plate portion 610 of the substrate receiving member contacts the contact portion 710 limiting their further movements. As shown, the contact flap 700 can expand partially through a gap (noted as k) between the wall structure 530 and the plate portion 610, and the degree of partial expansion can be controlled via the size of the gap k and the thickness of the contact flap 700. When a restoring force of the partially expanded portion through the gap, a force due to fluid pressure, and a reaction force by the wall structure 530 are in equilibrium, the partial expansion stops and the contact portion 710 gets to contact firmly the inner surface 614 of the plate portion 610. Then even though the fluid pressure P2 in the center chamber 300 is higher than the fluid pressure P1 in the outer chamber 200, gaps through which the fluid can flow from the center chamber 300 to the outer chamber 200 are removed. The center chamber 300 becomes a pressurizing chamber by taking the contact flap 700 as a chamber wall. On the other hand, when the fluid pressure P1 in the outer chamber 200 is higher than the fluid pressure P2 in the center chamber 300, the fluid can flow from the outer chamber 200 to the center chamber 300 because a firm contact between the contact portion 710 and the inner surface 614 of the substrate receiving member is not made.

Therefore, referring FIG. 2 and FIG. 5, the carrier head 900 for a chemical mechanical polishing apparatus comprises: a base 100; a substrate receiving member 600 connected to a lower part of the base 100, having an outer surface 612 for receiving a substrate and an inner surface 614 at the opposite side of the outer surface 612; at least one contact flap 700 positioned inside of the substrate receiving member 600 comprising a connecting portion 730 connected to the lower part of the base 100, a side portion 720 extended downwardly from the connecting portion 730, a contact portion 710 extended sidewardly from a bottom end of the side portion 720; at least one wall structure 530 connected to the lower part of the base 100, the at least one wall structure 530 being positioned adjacent to the at least one contact flap 700; wherein the at least one wall structure 530 is configured to limit an expansion of the at least one contact flap 700 for a firm contact of the contact portion 710 with the inner surface 614 by means of fluid pressure.

FIG. 6 is a partial cross-sectional view showing another example of a contact flap 760. In FIG. 5, a partial expansion of the contact flap 700 through the gap (k) between the wall structure 530 and the substrate receiving member 600 is shown. The partial expansion like this can alter the area of pressurized zone and reduce a life time of the contact flap 700. Therefore, as shown in FIG. 6, by forming a protruding structure 740 on a corner where the top surface 714 of the contact portion and the side portion 720 meet each other the partial expansion through the gap can be suppressed. As shown, the protruding structure 740 can have a shape of a step, where a width s can be in a range of 2 mm to 15 mm and a height h can be in a range of 1 mm to 7 mm. The protruding structure 740 is preferably made of the same material as the contact flap 760, and can be formed at the same time when the contact flap 760 is made.

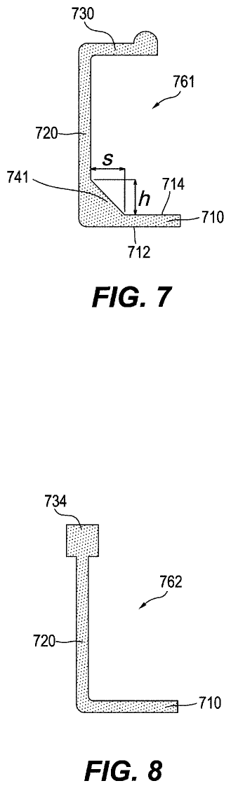

FIG. 7 is a partial cross-sectional view of yet another example of a contact flap 761 showing that a protruding structure can include an inclined surface. Although not shown, the protruding structure can include a curved surface. When a shape of the protruding structure 741 is defined as a single surface like this, the width s and height h of the protruding structure can be defined as the intersected lengths of the contact portion 710 and the side portion 720 with the protruding structure 741, respectively.

Therefore, referring FIGS. 6 and 7 respectively, the contact flap 760, 761 of a carrier head for a chemical mechanical polishing apparatus comprises: an annular contact portion 710 having a bottom surface 712 to provide a contact surface to a substrate receiving member and a top surface 714 at the opposite side of the bottom surface; a side portion 720 extended upwardly from the top surface 714; a connecting portion 730 extended in a side direction from a top end of the side portion 720; wherein a protruding structure 740, 741 is formed on at least one corner where the top surface 714 and the side portion 720 meet each other.

FIG. 8 is a partial cross-sectional view of still yet another example of a contact flap 762 showing that a connecting portion 734 is formed as a rim shape at the end of the side portion 720 without being extended from the side portion 720 as a flap shape. The connecting portion 734 like this does not need a vertical fastening for sealing. Instead, since sealing can be done by fastening laterally with a band or the like, it can be used in a narrow space advantageously.

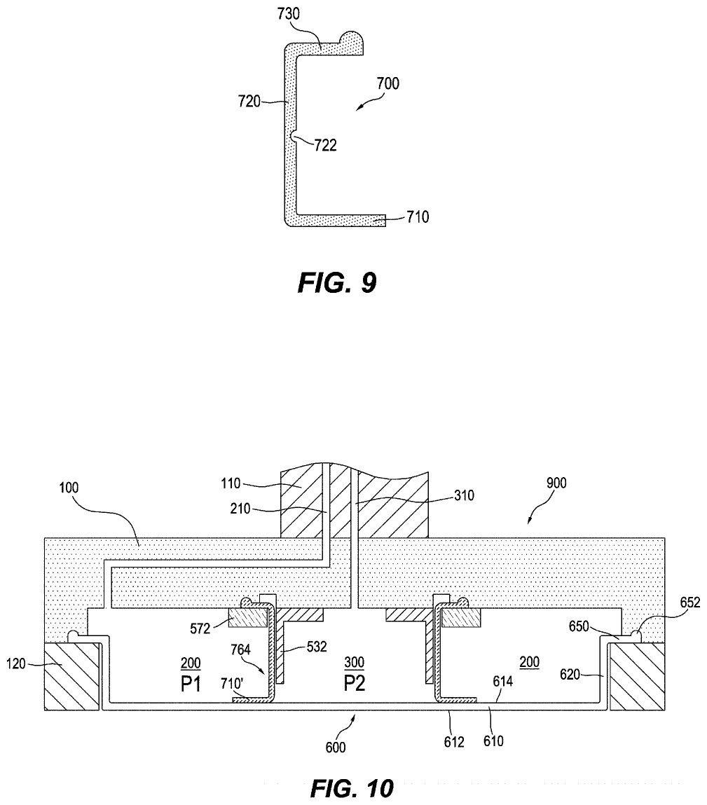

FIG. 9 is a partial cross-sectional view of still yet another example of a contact flap 700 showing that a groove 722 is formed at the side portion 720. The groove 722 formed along the cylindrical surface of the side portion 720 eases a bending of the side portion 722. This easy bending can help the plate portion 610 suffer less resistance when vacuum is applied to the center chamber 300 and outer chamber 200, and thereby the plate portion 610 is lifted up. Although only one groove 722 is shown in the figure, plural grooves can be formed.

FIG. 10 is a cross-sectional view of a carrier head 900 according to another embodiment of the present invention. When the fluid pressure P1 in the outer chamber 200 is higher than the fluid pressure P2 in the center chamber 300, fluid flow from the outer chamber 200 to the center chamber 300 can be suppressed by using a contact flap 764 whose contact portion 710′ is extended outwardly. Since the contact portion 710′ is extended outwardly, a wall structure 532 is positioned inside being opposite to the extended direction of the contact portion 710′. In addition, a clamp 572 is positioned outside contrary to the FIG. 2 explained above.

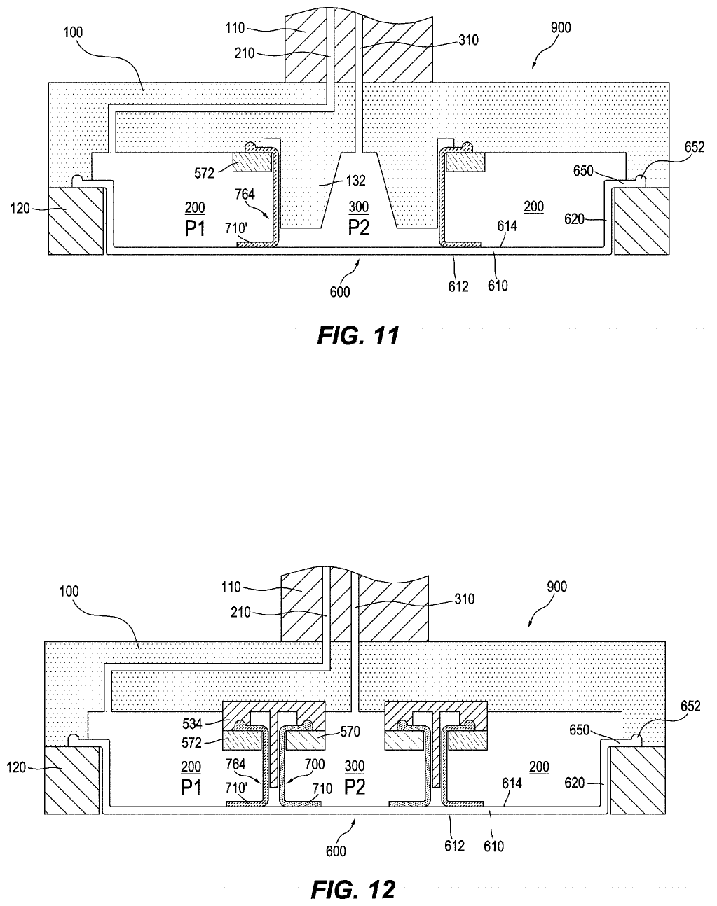

FIG. 11 is a cross-sectional view of a carrier head 900 according to yet another embodiment of the present invention showing that a protruded portion of the base 100 acts as a wall structure 132. In this case also the position of the wall structure 132 is opposite to the extended direction of the contact portion 710′.

FIG. 12 is a cross-sectional view of a carrier head 900 according to still yet another embodiment of the present invention showing that 2 contact flaps 700, 764 are mounted on a wall structure 534 and connected to the lower part of the base 100. As shown, the wall structure 534 between the two contact flaps 700, 764 is a shape of being at the opposite position at the same time to the extended direction of each contact portion 710, 710′. The contact flap 700 whose contact portion 710 is extended inwardly can suppress fluid flow from the center chamber 300 to the outer chamber 200 while the contact flap 764 whose contact portion 710′ is extended outwardly can suppress reverse fluid flow. Therefore, the carrier head 900 shown can suppress fluid flow from one chamber to the other irrespective of the relative magnitude between the pressure P1 in the outer chamber 200 and pressure P2 in the center chamber 300.

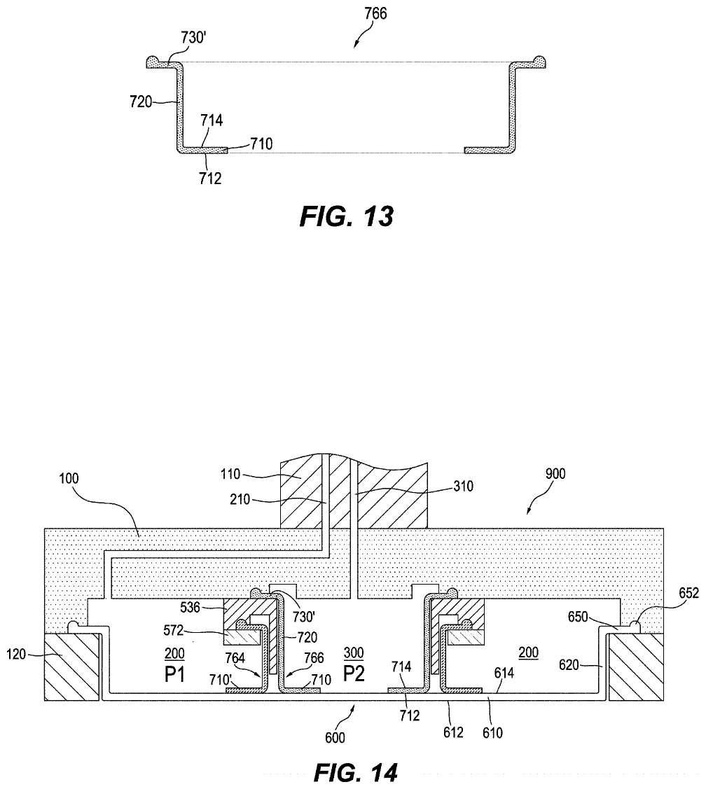

FIGS. 13 and 14 are cross-sectional views showing still yet another example of a contact flap and a carrier head using this contact flap, respectively. FIG. 13 shows a contact flap 766 whose contact portion 710 and connecting portion 730′ are extended in opposite directions with respect to the side portion 720. Although not shown, the side portion 720 can be extended upwardly from an inner edge of the contact portion 710 and the connecting portion can be extended inwardly opposite to the extended direction of the contact portion 710. Although not shown too, the protruding structure 740, 741 in FIG. 6 or 7 can be formed on a corner where the top surface 714 and the side portion 720 meet each other. FIG. 14 shows a carrier head 900 equipped with the contact flap 766 above and the contact flap 764 whose contact portion and connecting portion have a same extended direction. As shown, the contact flaps 764, 766 can be connected to the lower part of the base by only one wall structure 536 and one clamp 572.

Therefore, referring FIGS. 13 and 14, the contact flap 766 of a carrier head for a chemical mechanical polishing apparatus comprises: an annular contact portion 710 having a bottom surface 712 to provide a contact surface to a substrate receiving member and a top surface 714 at the opposite side of the bottom surface 712; a side portion 720 extended upwardly from an either inner or outer edge of the top surface 714; a connecting portion 730′ extended in a side direction from a top end of the side portion 720, the side direction being opposite to an extended direction of the contact portion 710.

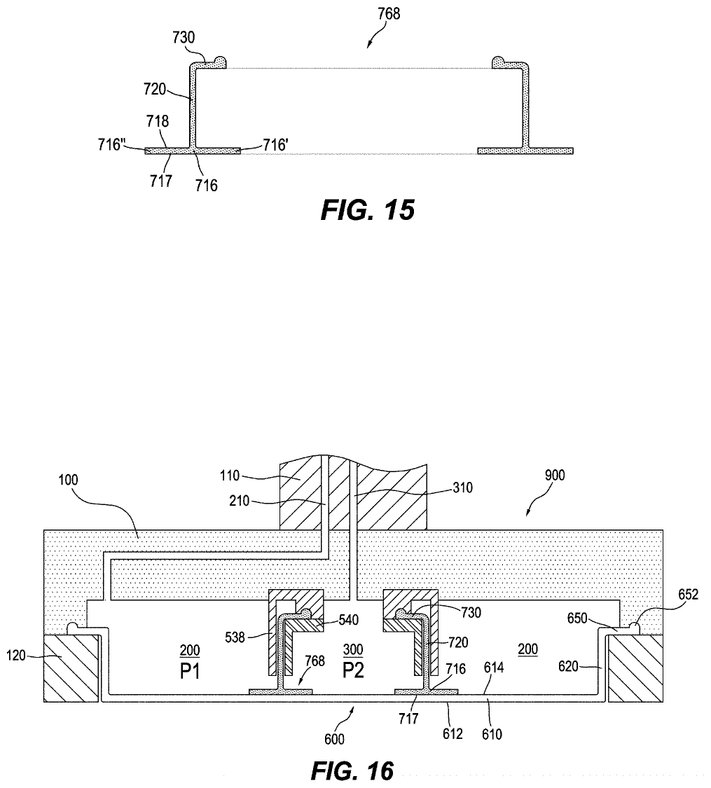

FIGS. 15 and 16 are cross-sectional views showing still yet another example of a contact flap 768 and a carrier head 900 using this contact flap, respectively. Referring FIG. 15 first, the side portion 720 is extended upwardly from a surface between inner and outer edges of a top surface 718 of a contact portion 716 (for example from a center location between the two edges) and the connecting portion 730 is extended inwardly from a top end of the side portion 720. Although not shown, the connecting portion 730 can be extended outwardly. Accordingly, the contact portion 716 is divided into two contact portion parts 716′, 716″ which extend bi-directionally inward and outward with respect to the side portion 720. The contact portion part 716′ extended inwardly is used to suppress fluid flow from the inside to the outside and the contact portion part 716″ extended outwardly is used to suppress fluid flow from the outside to the inside. Although it is shown that the two contact portion parts 716′, 716″ are symmetric with respect to the side portion 720, two contact portion parts can have different thicknesses or extended lengths. FIG. 16 shows the contact flap 768 is connected to the lower part of the base 100 after being secured by two wall structures 538, 540. Like this, owing to the contact portion 716 extended bi-directionally and the wall structures 538, 540, the single contact flap 768 can suppress fluid flow bi-directionally between the two chambers 200, 300.

Therefore, referring FIGS. 15 and 16, the contact flap 768 of a carrier head for a chemical mechanical polishing apparatus comprises: an annular contact portion 716 having a bottom surface 717 to provide a contact surface to a substrate receiving member and a top surface 718 at the opposite side of the bottom surface 717; a side portion 720 extended upwardly from a surface between inner and outer edges of the top surface 718; a connecting portion 730 extended in a side direction from a top end of the side portion 720, the side direction being either inward or outward with respect to the side portion 720.

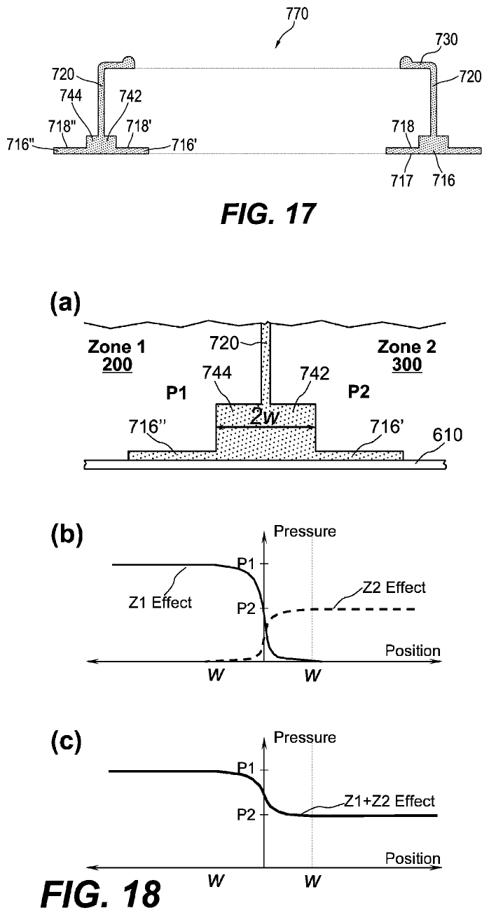

FIG. 17 is a cross-sectional view of still yet another example of a contact flap showing that protruding structures 742, 744 are formed on corners where the side portion 720 and the top surface 718 of the contact portion 716 meet each other. Since the contact portion 716 is divided into the two contact portion parts 716′, 716″ where one is extended inwardly and the other is extended outwardly with respect to the side portion 720, the top surface 718 can be divided into top surface inner part 718′ and top surface outer part 718″. Although step-shaped protruding structures 742, 744 which are mutually symmetric are shown in the figure, protruding structures having different shapes and sizes can be formed at each corner where the top surface inner part 718′ or the top surface outer part 718″ meet with the side portion 720. Furthermore, only one protruding structure can be formed on either of the corners. As explained above in the FIG. 6, the protruding structures 742, 744 can suppress a partial expansion through a gap between a wall structure and a substrate receiving member.

FIG. 18 is a partial cross-sectional view of a carrier head, and graphs of pressure variation according to the position of the plate portion 610 for explaining pressure dispersion by protruding structures 742, 744 whose total width is 2w. Referring FIG. 18(a) first, a pressure P1 is applied to the outer chamber 200 noted as Zone 1 and a pressure P2 is applied to the center chamber 300 noted as Zone 2. These pressures are transferred to the plate portion 610 directly or through the contact portions 716′, 716″ and the protruding structures 742, 744. When the pressure P1 in the outer chamber 200 is acting on the top of the protruding structure 744, this pressure P1 is dispersed to the neighboring protruding structure 742 as coming down to the plate portion 610. As a result, the pressure acting on the plate portion 610 from the outer chamber 200 according to position is varied like the graph Z1 Effect of FIG. 18(b). Likewise, when the pressure P2 in the center chamber 300 is acting on the top of the protruding structure 742, this pressure P2 is dispersed to the neighboring protruding structure 744 as coming down to the plate portion 610. As a result, the pressure acting on the plate portion 610 from the center chamber 300 according to position is varied like the graph Z2 Effect of FIG. 18(b). Accordingly, the pressure finally applied to the plate portion 610 is produced by adding all pressures applied to the plate portion 610, so that it is varied as shown by the graph Z1+Z2 effect of FIG. 18(c). Here, it can be appreciated that through the protruding structures 742, 744, the pressure applied to the plate portion 610 is not sharply varied when moving from the Zone 1 of the outer chamber 200 to the Zone 2 of the center chamber 300.

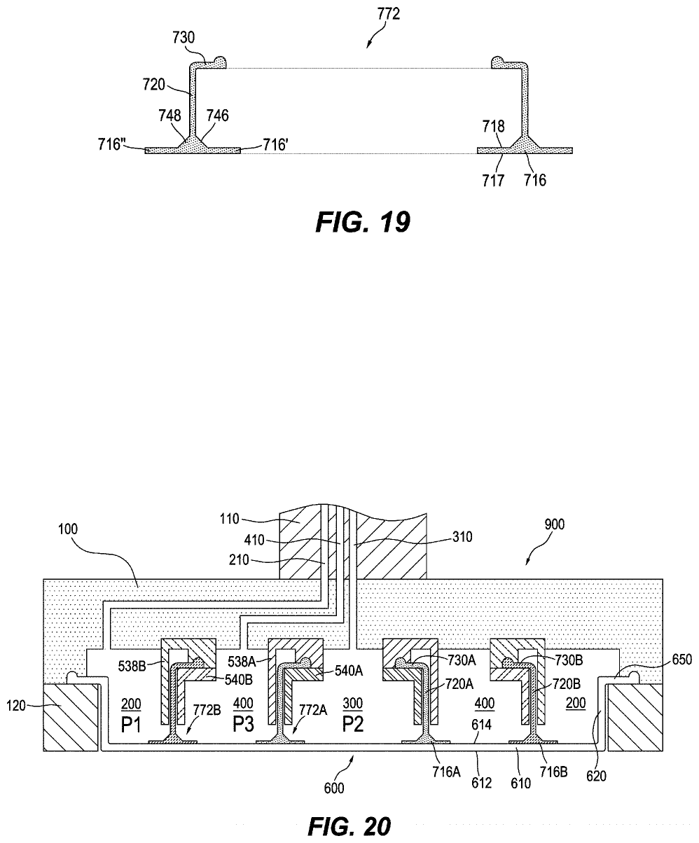

FIG. 19 is a cross-sectional view of a contact flap 772 showing another example of a protruding structure 746, 748. The protruding structures 746, 748 have inclined surfaces as shown. A pressure applied to an inclined surface can be directly transferred across the side portion 720 to the contact portion in the opposite side. For example, a pressure applied to the outer protruding structure 748 acts also to the inner protruding structure 746 and the inner contact portion part 716′. Therefore, protruding structures having an inclined surface (for example inclined angle of 45°) can be effective in generating a gradual pressure variation. Protruding structures can have a shape of step and can include an inclined surface or a curved surface. The shape and size of protruding structure are preferably decided in the light of the effect on the suppression of expansion and pressure dispersion.

Therefore, referring FIGS. 17 and 19, the contact flap 770, 772 of a carrier head for a chemical mechanical polishing apparatus comprises: an annular contact portion 710 having a bottom surface 717 to provide a contact surface to a substrate receiving member and a top surface 718 at the opposite side of the bottom surface; a side portion 720 extended upwardly from the top surface 718; a connecting portion 730 extended in a side direction from a top end of the side portion 720; wherein a protruding structure 742, 744, 746, 748 is formed on at least one corner where the top surface 718 and the side portion 720 meet each other.

FIG. 20 is a cross-sectional view of a carrier head 900 according to still yet another embodiment of the present invention. An outer chamber 200, a center chamber 300 and an intermediate chamber 400 can be formed by two contact flaps 772A, 772B and four wall structures 538A, 540A, 538B, 540B. Pressures P1, P2 and P3 can be applied independently to each chamber 200, 300 and 400 through fluid passages 210, 310 and 410. Like this, using contact flaps and wall structures, pressures can be applied independently to predetermined areas of the plate portion 610 of the substrate receiving member. These applied pressures are directly transferred to a mounted substrate (not shown) during polishing, which can be used in controlling the polishing rate of each area.

Therefore, referring FIG. 20, the carrier head 900 for a chemical mechanical polishing apparatus comprises: a base 100; a substrate receiving member 600 connected to a lower part of the base 100, having an outer surface 612 for receiving a substrate and an inner surface 614 at the opposite side of the outer surface 612; at least one contact flap 772A, 772B positioned inside of the substrate receiving member 600 comprising a connecting portion 730A, 730B connected to the lower part of the base 100, a side portion 720A, 720B extended downwardly from the connecting portion 730A, 730B, a contact portion 716A, 716B extended sidewardly from a bottom end of the side portion 720A, 720B; at least one wall structure 538A, 540A, 538B, 540B connected to the lower part of the base 100, the at least one wall structure 538A, 540A, 538B, 540B being positioned adjacent to the at least one contact flap 772A, 772B; wherein the at least one wall structure 538A, 540A, 538B, 540B is configured to limit an expansion of the at least one contact flap 772A, 772B for a firm contact of the contact portion 716A, 716B with the inner surface 614 by means of fluid pressure.

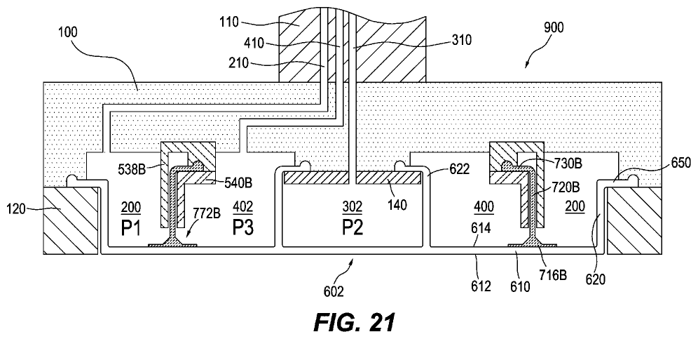

FIG. 21 is a cross-sectional view of a carrier head 900 according to still yet another embodiment of the present invention, where a substrate receiving member 602 can further comprise an annular partition portion 622 extended upwardly from the inner surface 614 of the plate portion 610. As shown a center chamber 302 is formed by taking the partition portion 622 as a chamber wall when an end of the partition portion 622 is connected to the lower part of the base 100 with a clamp 140.

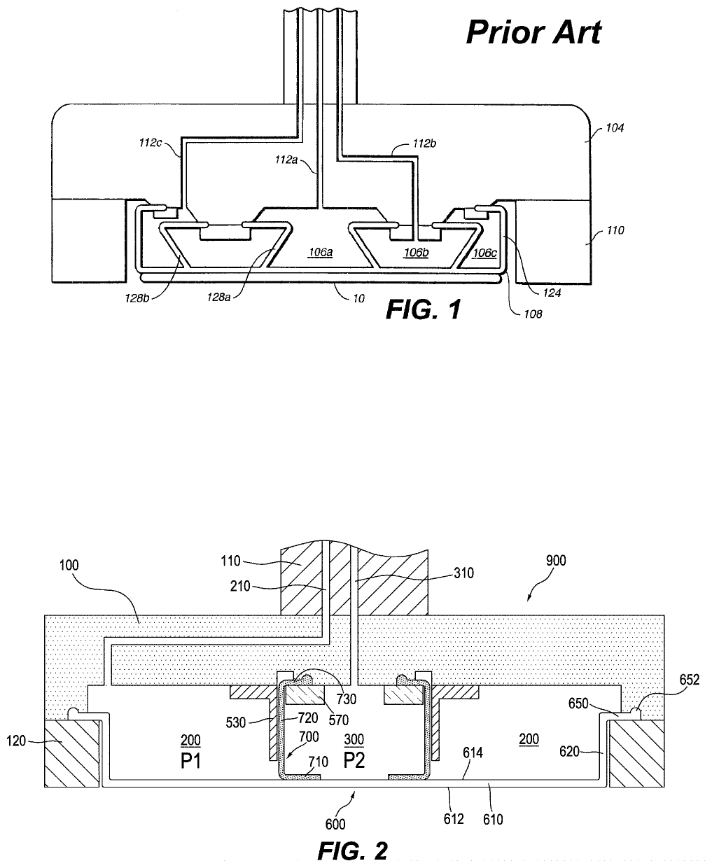

The substrate receiving member 602 above is a substrate receiving member according to the prior art shown in FIG. 1 in that it forms a pressurizing chamber (such as the center chamber 302) surrounded with the partition portion 622. Moreover, it can form a pressurizing chamber with a contact flap of the present invention which acts as side chamber wall paired with the partition portion 622. For example, as shown in FIG. 21, if a pressure P3 is applied through the fluid passage 410, an annular pressurizing chamber 402 is formed, where the partition portion 622 acts as an inner side chamber wall and the contact flap 772B located outer side acts as an outer side chamber wall through a firm contact with the inner surface 614. Although FIG. 21 shows that only one partition portion 622 positions inside of only one contact flap 772, the carrier head can include plural partition portions and contact flaps, where a partition portion may position outside of a contact flap.

### MODE FOR INVENTION

The preferred embodiments of the present invention have been sufficiently explained in the description for the best mode for the invention, and accordingly, an explanation on them will be omitted for the brevity of the description.

### INDUSTRIAL APPLICABILITY

The carrier head for a chemical mechanical polishing apparatus comprising contact flap according to the present invention is applicable to chemical mechanical polishing process required to fabricate semiconductor or glass substrates, and integrated circuits.

1. A carrier head for a chemical mechanical polishing apparatus, the carrier head comprising:
a base;
a substrate receiving member connected to a lower part of the base, having an outer surface for receiving a substrate and an inner surface at the opposite side of the outer surface;
at least one contact flap positioned inside of the substrate receiving member comprising a connecting portion connected to the lower part of the base, a side portion extended downwardly from the connecting portion, a contact portion extended sidewardly from a bottom end of the side portion;
at least one wall structure connected to the lower part of the base, the at least one wall structure being positioned adjacent to the at least one contact flap;
wherein the at least one wall structure is configured to limit an expansion of the at least one contact flap for a firm contact of the contact portion with the inner surface by means of fluid pressure.

2. The carrier head according to claim 1, wherein the at least one contact flap has an open structure with an annular shape.

3. The carrier head according to claim 1, wherein the at least one contact flap is formed of a flexible material.

4. The carrier head according to claim 1, wherein a pressurizing chamber is formed taking the at least one contact flap as a chamber wall through a firm contact of the contact portion with the inner surface by means of fluid pressure.

5. The carrier head according to claim 1, wherein the contact portion is extended either inwardly or outwardly.

6. The carrier head according to claim 1, wherein the contact portion is extended bidirectionally, both inwardly and outwardly.

7. The carrier head according to claim 1, wherein the at least one wall structure adjacent to the at least one contact flap is positioned at the opposite side to an extended direction of the contact portion.

8. The carrier head according to claim 1, wherein the substrate receiving member further comprises at least one annular partition portion extended upwardly from the inner surface.

9. The carrier head according to claim 8, wherein an annular pressurizing chamber is formed through the at least one partition portion and the at least one contact flap acting as paired side chamber walls.

10. A contact flap of a carrier head for a chemical mechanical polishing apparatus comprising:
an annular contact portion having a bottom surface to provide a contact surface to a substrate receiving member and a top surface at the opposite side of the bottom surface;
a side portion extended upwardly from the top surface;
a connecting portion extended in a side direction from a top end of the side portion;
wherein a protruding structure is formed on at least one corner where the top surface and the side portion meet each other.

11. The contact flap according to claim 10, wherein the protruding structure has a step shape.

12. The contact flap according to claim 10, wherein the protruding structure comprises an inclined surface.

13. The contact flap according to claim 10, wherein the protruding structure comprises a curved surface.

14. The contact flap according to claim 10, wherein the protruding structure has a height of 2 to 14 mm and a width of 1 to 7 mm.

15. A contact flap of a carrier head for a chemical mechanical polishing apparatus comprising:
an annular contact portion having a bottom surface to provide a contact surface to a substrate receiving member and a top surface at the opposite side of the bottom surface;
a side portion extended upwardly from an either inner or outer edge of the top surface;
a connecting portion extended in a side direction from a top end of the side portion, the side direction being opposite to an extended direction of the contact portion.

16. A contact flap of a carrier head for a chemical mechanical polishing apparatus comprising:
an annular contact portion having a bottom surface to provide a contact surface to a substrate receiving member and a top surface at the opposite side of the bottom surface;
a side portion extended upwardly from a surface between inner and outer edges of the top surface;
a connecting portion extended in a side direction from a top end of the side portion, the side direction being either inward or outward with respect to the side portion.
